(19) United States
(12) Patent Application Publication
(10) Pub. No.: US 2021/0325826 A1
(43) Pub. Date: Oct. 21, 2021

(54) APPARATUS FOR DISPLAYING HOLOGRAM

(71) Applicant: Electronics and Telecommunications Research Institute, Daejeon (KR)

(72) Inventors: Sang Hoon CHEON, Daejeon (KR); Yong Hae KIM, Daejeon (KR); Seong-Mok CHO, Daejeon (KR); Kyunghee CHOI, Daejeon (KR); Chi-Sun HWANG, Daejeon (KR)

(73) Assignee: Electronics and Telecommunications Research Institute, Daejeon (KR)

(21) Appl. No.: 17/232,955

(22) Filed: Apr. 16, 2021

(30) Foreign Application Priority Data
Apr. 17, 2020 (KR) 10-2020-0046689

(51) Int. Cl. G03H 1/22

(52) U.S. Cl. CPC G03H 1/2294; H01L 27/3258

(57) ABSTRACT

Disclosed is an apparatus for displaying a hologram including a pixel circuit array including first to n^{th} pixel circuits, a first insulating layer provided on the pixel circuit array, first to n^{th} pixel electrodes provided on the first insulating layer and electrically connected to the first to n^{th} pixel circuits, respectively, a second insulating layer provided on the first insulating layer, first to n^{th} display electrodes provided on the second insulating layer and electrically connected to the first to n^{th} pixel electrodes, respectively, a display panel formed on the first to n^{th} display electrodes, and a common electrode formed on the display panel. The first to n^{th} display electrodes are clustery formed, and an area of the first to n^{th} display electrodes is smaller than an area of the pixel circuit array.

### CROSS-REFERENCE TO RELATED APPLICATIONS

This application claims priority under 35 U.S.C. § 119 to Korean Patent Application No. 10-2020-0046689 filed on Apr. 17, 2020, in the Korean Intellectual Property Office, the disclosures of which are incorporated by reference herein in their entireties.

### BACKGROUND

Embodiments of the present disclosure described herein relate to a digital holography technology, and more particularly, relate to an apparatus for displaying a hologram using display electrodes in a clustery shape.

Unlike a conventional method using optical illusion of eyes to create a three-dimensional effect, a holography method may directly see image forming, thereby providing the three-dimensional effect that does not differ from viewing reality. The holographic technology draws attention as a next-generation stereoscopic image technology because eye strain which appears in a manner of viewing an image using binocular parallax is fundamentally avoided. Unlike a method of producing two-dimensional image that records only intensity of light, the holography technology reproduces a three-dimensional image by recording intensity and phase of light.

A hologram capable of being generated using the holographic technology may be classified into an analog hologram, a pseudo hologram, and a digital hologram. The analog hologram refers to a hologram in which a real subject is produced as a three-dimensional image using a film. The pseudo hologram refers to a hologram produced as a semi-transmissive screen projection image or a super-multiview stereoscopic image. The digital hologram refers to a hologram produced using data generated by digitizing light reflected from a subject. The digital hologram is in the spotlight as an ultimate technique of producing the three-dimensional image, which produces not only a still image, but also a moving image or various digital contents.

For efficiently producing the digital hologram, a method of attaching a random phase mask to a panel displaying a hologram may be used. When the random phase mask is used, a wide viewing angle corresponding to a pitch of the random phase mask may be secured, and an amount of light transmitted may be maintained. However, when an interval between the random phase mask and a panel displaying the hologram is non-uniformly formed due to a process error, the viewing angle cannot be obtained.

For efficiently producing the digital hologram, a method of attaching a mask in which pinholes are arranged on a panel displaying a hologram may be used. When the mask in which the pinholes are arranged is used, a viewing angle corresponding to a size of the pinhole may be secured. To use the mask in which the pinholes are arranged, one pinhole should be arranged per pixel of the panel displaying the hologram, thereby controlling a display value of the hologram image. In manufacturing the mask in which the pinholes are arranged, when a periodic pinhole arrangement is generated, it is easy in terms of a manufacturing process, but a repetitive image may be generated by a periodic sampling effect. In addition, because the smaller a fill-factor of the pinhole for the pixel of the panel displaying the hologram, the more severe the noise, it is difficult to produce a clear holographic image.

### SUMMARY

Embodiments of the present disclosure provide an apparatus for displaying a hologram capable of implementing a holographic image which has reduced noise and an extended viewing angle.

According to an embodiment, an apparatus for displaying a hologram includes a pixel circuit array including first to n^{th} pixel circuits, a first insulating layer provided on the pixel circuit array, first to n^{th} pixel electrodes provided on the first insulating layer and electrically connected to the first to n^{th} pixel circuits, respectively, a second insulating layer provided on the first insulating layer, first to n^{th} display electrodes provided on the second insulating layer and electrically connected to the first to n^{th} pixel electrodes, respectively, a display panel formed on the first to n^{th} display electrodes, and a common electrode formed on the display panel, and the first to n^{th} display electrodes are clustery formed, and an area of the first to n^{th} display electrodes is smaller than an area of the pixel circuit array.

According to an embodiment, the first to n^{th} display electrodes are clustery formed in a square.

According to an embodiment, the first to n^{th} display electrodes are clustery formed in a rectangular shape.

According to an embodiment, the first insulating layer and the second insulating layer include the same material.

According to an embodiment, the first insulating layer and the second insulating layer include an organic insulator.

According to an embodiment, the display panel includes a liquid crystal (LC), an electrochromic (EC), an organic light-emitting diode (OLED), or a quantum dot.

According to an embodiment, an apparatus for displaying the hologram includes a pixel circuit array including first to n^{th} pixel circuits, an insulating layer provided on the pixel circuit array, first to n^{th} display electrodes provided on the insulating layer and electrically connected to the first to n^{th} pixel circuits, respectively, a display panel formed on the first to n^{th} display electrodes, and a common electrode formed on the display panel, and the first to n^{th} display electrodes are clustery formed, and an area of the first to n^{th} display electrodes is smaller than an area of the pixel circuit array.

According to an embodiment, the first to n^{th} display electrodes are clustery formed in a square.

According to an embodiment, the first to n^{th} display electrodes are clustery formed in a rectangular shape.

According to an embodiment, the insulating layer includes an organic insulator.

According to an embodiment, the display panel includes a liquid crystal (LC), an electrochromic (EC), an organic light-emitting diode (OLED), or a quantum dot.

### BRIEF DESCRIPTION OF THE FIGURES

The above and other objects and features of the present disclosure will become apparent by describing in detail embodiments thereof with reference to the accompanying drawings.

FIG. 1A is a view illustrating a structure of an apparatus for displaying a hologram according to an embodiment of the present disclosure;

FIG. 1B is a view illustrating a structure of an apparatus for displaying a hologram according to another embodiment of the present disclosure;

FIG. 1C is a cross-sectional view taken along a line I-I′ of the apparatus for displaying the hologram illustrated in FIG. 1A;

FIG. 1D is a cross-sectional view taken along a line I-I′ of the apparatus for displaying the hologram illustrated in FIG. 1B;

FIG. 1E is a plan view of the apparatus for displaying the hologram illustrated in FIG. 1A;

FIG. 2A is a view illustrating a result of calculating hologram data CGH;

FIG. 2B is a view illustrating pixel data output from a pixel cluster of an apparatus for displaying a hologram according to an embodiment of the present disclosure;

FIG. 3A is a view illustrating a structure of an apparatus for displaying a hologram according to an embodiment of the present disclosure;

FIG. 3B is a view illustrating a structure of an apparatus for displaying a hologram according to another embodiment of the present disclosure;

FIG. 3C is a cross-sectional view taken along a line I-I′ of the apparatus for displaying the hologram illustrated in FIG. 3A;

FIG. 3D is a cross-sectional view taken along a line I-I′ of the apparatus for displaying the hologram illustrated in FIG. 3B;

FIG. 3E is a plan view of the apparatus for displaying the hologram illustrated in FIG. 3A;

FIG. 4 is a view illustrating pixel data output from a pixel cluster of an apparatus for displaying a hologram according to another embodiment of the present disclosure;

FIG. 5A is a view illustrating a structure of an apparatus for displaying a hologram according to an embodiment of the present disclosure;

FIG. 5B is a view illustrating a structure of an apparatus for displaying a hologram according to another embodiment of the present disclosure;

FIG. 5C is a plan view of the apparatus for displaying the hologram illustrated in FIG. 5A;

FIG. 6A is a view illustrating a result of calculating other hologram data CGH;

FIG. 6B is a view illustrating pixel data output from a pixel cluster of an apparatus for displaying a hologram according to another embodiment of the present disclosure;

FIG. 7A is a view illustrating a structure of an apparatus for displaying a hologram according to an embodiment of the present disclosure;

FIG. 7B is a view illustrating a structure of an apparatus for displaying a hologram according to another embodiment of the present disclosure;

FIG. 7C is a plan view of the apparatus for displaying the hologram illustrated in FIG. 7A.

FIG. 8A is a view illustrating a result of calculating other hologram data CGH;

FIG. 8B is a view illustrating pixel data output from a pixel cluster of an apparatus for displaying a hologram according to another embodiment of the present disclosure; and

FIGS. 9A to 9D are views illustrating simulation results of a hologram image implemented from an apparatus for displaying a hologram according to an embodiment of the present disclosure.

### DETAILED DESCRIPTION

Hereinafter, embodiments of the present disclosure will be described clearly and in detail to the extent that one of ordinary skill in the technical field of the present disclosure may easily implement the present disclosure.

The terms used in the specification are for explaining embodiments, and are not intended to limit the present disclosure. A singular form, unless otherwise stated, includes a plural form. It will be understood that the terms “comprise” and/or “comprising:” specify the presence of features, steps, operations, and/or elements described in the specification, or a combination thereof, not precluding the presence or additional possibility of one or more other features, steps, operations, and/or elements.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. Like reference numerals refer to like components in the entire specification.

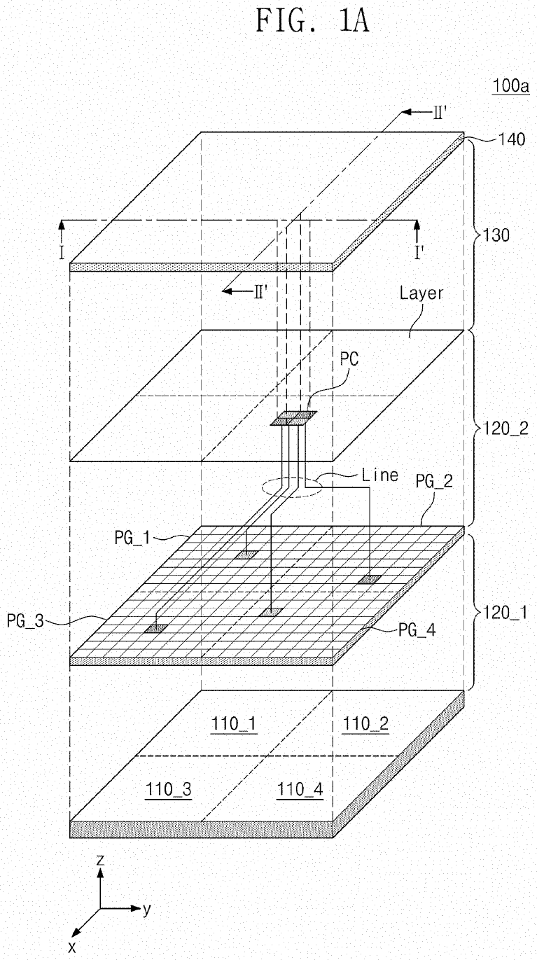

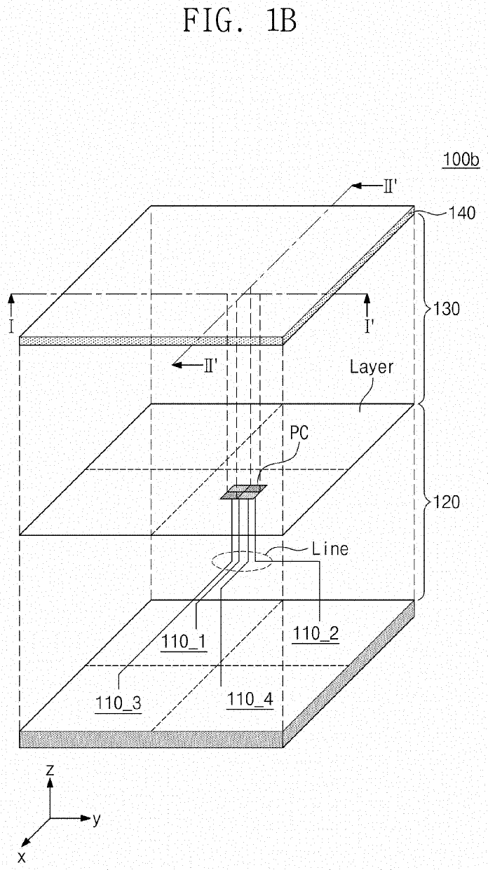

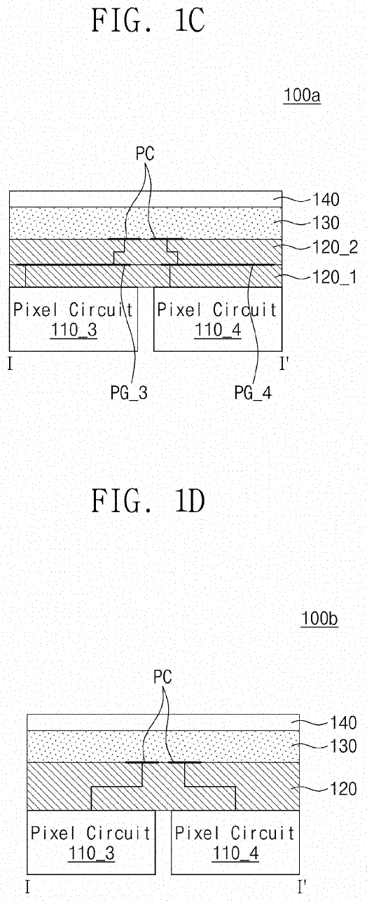

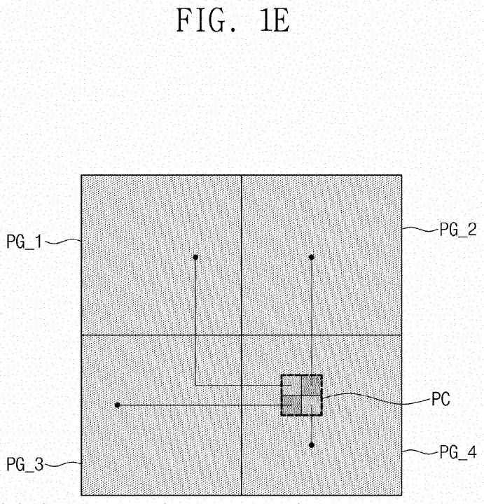

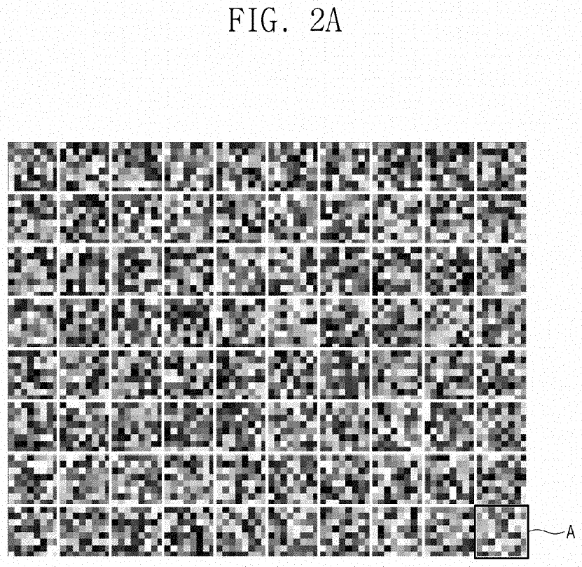

FIG. 1A is a view illustrating a structure of an apparatus for displaying a hologram according to an embodiment of the present disclosure.

Referring to FIG. 1A, an apparatus 100a for displaying a hologram according to an embodiment of the present disclosure may include first to fourth pixel circuits 110_1, 110_2, 110_3, and 110_4, a first insulating layer 120_1, first to fourth pixel groups PG_1, PG_2, PG_3, and PG_4, a second insulating layer 120_2, a pixel cluster PC, a display panel 130, and a common electrode 140. The first to fourth pixel circuits 110_1, 110_2, 110_3, and 110_4 may be disposed in an x direction and a y direction to form an array. FIG. 1A illustrates the first to fourth pixel circuits 110_1, 110_2, 110_3, and 110_4 are arranged in (2×2).

The first insulating layer 120_1 may be formed on the first to fourth pixel circuits 110_1, 110_2, 110_3, and 110_4. The first to fourth pixel groups PG_1, PG_2, PG_3, and PG_4 respectively corresponding to the first to fourth pixel circuits 110_1, 110_2, 110_3, and 110_4 may be formed on the first insulating layer 120_1. The pixel group refers to a plurality of pixel electrodes corresponding to one pixel circuit. For example, the first pixel group PG_1 means a plurality of pixel electrodes corresponding to the first pixel circuit 110_1.

The first to fourth pixel groups PG_1, PG_2, PG_3, and PG_4 may be disposed in the x direction and the y direction to form an array. FIG. 1A illustrates the first to fourth pixel groups PG_1, PG_2, PG_3, and PG_4 are arranged in (2×2). In addition, it is shown that the plurality of pixel electrodes included in each of the first to fourth pixel groups PG_1, PG_2, PG_3, and PG_4 are arranged in (8×8) in the x direction and the y direction. The first to fourth pixel groups PG_1, PG_2, PG_3, and PG_4 and the first to fourth pixel circuits 110_1, 110_2, 110_3, and 110_4 corresponding to first to fourth pixel groups PG_1, PG_2, PG_3, and PG_4 may be electrically connected through lines, respectively.

The second insulating layer 120_2 may be stacked on the first to fourth pixel groups PG_1, PG_2, PG_3, and PG_4. The first insulating layer 120_1 and the second insulating layer 120_2 may be formed of the same material or different materials. The first insulating layer 120_1 or the second insulating layer 120_2 may include an organic insulator. A layer in which the pixel cluster PC is formed may be disposed on the second insulating layer 120_2.

The layer may include the pixel cluster PC. The pixel cluster PC means that a plurality of display electrodes are clustery arranged. Clustery arranged means that at least two display electrodes among the plurality of display electrodes included in one cluster are disposed adjacent to each other. FIG. 1A illustrates the pixel cluster PC includes four display electrodes, and the four display electrodes are arranged in (2×2) in the x direction and the y direction. The pixel cluster PC may be randomly disposed on a layer. Each of the display electrodes included in the pixel cluster PC may be electrically connected to at least one pixel electrode included in each of the first to fourth pixel groups PG_1, PG_2, PG_3, and PG_4 through the line.

The display panel 130 may be stacked on the layer. The display panel 130 may include a liquid crystal (LC), an electrochromic (EC), an organic light-emitting diode (OLED), or a quantum dot (QD). However, the above-described display particles are provided by way of example and do not limit the configuration of the display panel 130. The common electrode 140 may be stacked on the display panel 130. The common electrode 140 may include indium tin oxide (ITO), which is a transparent electrical conductor. The common electrode 140 may apply a voltage to the display panel 130.

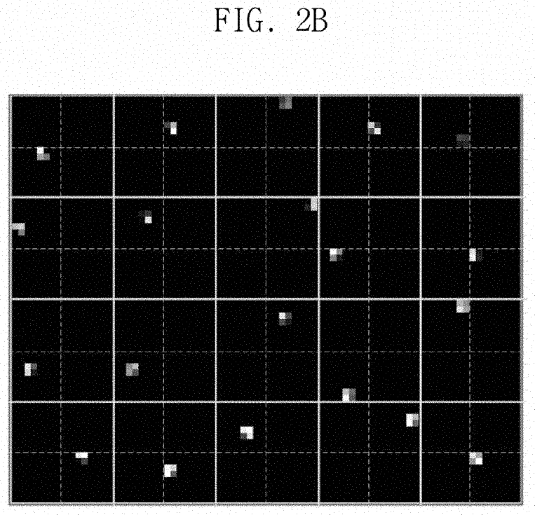

In the apparatus for displaying the hologram according to the present disclosure, the pixel cluster PC may serve as a pinhole included in a pinhole mask used to produce a conventional holographic image. The apparatus for displaying the hologram according to the present disclosure may provide an extended viewing angle through the pixel cluster PC and may provide a holographic image with reduced noise. A driving aspect of the apparatus 100a for displaying the hologram according to the embodiment of the present disclosure illustrated in FIG. 1A will be described in detail in FIGS. 2A to 2B to be described later.

FIG. 1B is a view illustrating a structure of an apparatus for displaying a hologram according to another embodiment of the present disclosure.

An apparatus 100b for displaying the hologram according to an embodiment of the present disclosure may include the first to fourth pixel circuits 110_1, 110_2, 110_3, and 110_4, an insulating layer 120, the pixel cluster PC, the display panel 130, and the common electrode 140. The first to fourth pixel circuits 110_1, 110_2, 110_3, and 110_4 may be disposed in the x direction and the y direction to form an array. FIG. 1B illustrates the first to fourth pixel circuits 110_1, 110_2, 110_3, and 110_4 are arranged in (2×2).

The insulating layer 120 may be stacked on the first to fourth pixel circuits 110_1, 110_2, 110_3, and 110_4. The insulating layer 120 may include an organic insulator. The layer may be disposed on the insulating layer 120. The layer refers to a top surface of the insulating layer 120 and does not mean a physical component. The layer may include the pixel cluster PC. FIG. 1B illustrates the pixel cluster PC including four display electrodes, and the four display electrodes are arranged in (2×2) in the x direction and the y direction. The pixel cluster PC may be randomly disposed on the layer. The display electrodes included in the pixel cluster PC may be electrically connected to the first to fourth pixel circuits 110_1, 110_2, 110_3, and 110_4 through the lines, respectively.

The display panel 130 may be stacked on the layer. The display panel 130 may include a liquid crystal (LC), an electrochromic (EC), an organic light-emitting diode (OLED), or a quantum dot (QD). However, the above-described display particles are provided by way of example and do not limit the configuration of the display panel 130. The common electrode 140 may be stacked on the display panel 130. The common electrode 140 may include indium tin oxide (ITO), which is a transparent electrical conductor. The common electrode 140 may apply a voltage to the display panel 130. The apparatus 100b for displaying the hologram illustrated in FIG. 1B may also provide an extended viewing angle through the pixel cluster PC and may provide a holographic image with reduced noise.

FIG. 1C is a cross-sectional view taken along a line I-I′ of the apparatus for displaying the hologram illustrated in FIG. 1A.

FIG. 1C illustrates the two pixel circuits 110_3 and 110_4 of the four pixel circuits 110_1, 110_2, 110_3, and 110_4 (refer to FIG. 1A). The first insulating layer 120_1 may be stacked on the third and fourth pixel circuits 110_3 and 110_4. The third and fourth pixel groups PG_3 and PG_4 may be formed on the first insulating layer 120_1. Each of the pixel groups PG_3 and PG_4 includes the plurality of pixel electrodes, but in FIG. 1C, the pixel electrodes constituting the pixel groups PG_3 and PG_4 are not illustrated for simplicity. The third and fourth pixel groups PG_3 and PG_4 may correspond to and be electrically connected to the third and fourth pixel circuits 110_3 and 110_4, respectively. The second insulating layer 120_2 may be stacked on the third and fourth pixel groups PG_3 and PG_4. The pixel cluster PC may be formed on the second insulating layer 120_2.

FIG. 1C illustrates the two display electrodes among the four display electrodes shown in FIG. 1A. The plurality of display electrodes included in the pixel cluster PC may be clustery arranged. Each of the plurality of display electrodes may be connected to an arbitrary pixel electrode included in each of the plurality of pixel groups PG_1, PG_2, PG_3, and PG_4 (refer to FIG. 1A). FIG. 1C conceptually illustrates that each of the two display electrodes is electrically connected to an arbitrary pixel electrode included in each of the third and fourth pixel groups PG_3 and PG_4. The display panel 130 may be stacked on the second insulating layer 120_2, and the common electrode 140 may be stacked on the display panel 130. A cross-sectional view of the apparatus 100a for displaying the hologram shown in FIG. 1A taken along a line II-II′ is also the same as that of FIG. 1C.

FIG. 1D is a cross-sectional view taken along a line I-I′ of the apparatus for displaying the hologram illustrated in FIG. 1B.

FIG. 1D illustrates the two pixel circuits 110_3 and 110_4 of the four pixel circuits 110_1, 110_2, 110_3, and 110_4 (refer to FIG. 1B) shown in FIG. 1B. The insulating layer 120 may be stacked on the third and fourth pixel circuits 110_3 and 110_4. The pixel cluster PC may be formed on the insulating layer 120.

FIG. 1D illustrates the two display electrodes of the four display electrodes shown in FIG. 1B. The plurality of display electrodes included in the pixel cluster PC may be clustery arranged. The plurality of display electrodes may be electrically connected to the plurality of pixel circuits 110_1, 110_2, 110_3, and 110_4 (refer to FIG. 1B), respectively. FIG. 1D conceptually illustrates that the two display electrodes are electrically connected to the third and fourth pixel circuits 110_3 and 110_4, respectively. The display panel 130 may be stacked on the insulating layer 120, and the common electrode 140 may be stacked on the display panel 130. A cross-sectional view of the apparatus 100b for displaying the hologram shown in FIG. 1B taken along a line II-II′ is also the same as that of FIG. 1D.

FIG. 1E is a plan view of the apparatus for displaying the hologram illustrated in FIG. 1A.

In more detail, FIG. 1E illustrates the first to fourth pixel groups PG_1, PG_2, PG_3, and PG_4 (refer to FIG. 1A), the pixel cluster PC including the four display electrodes, and a wiring structure between the pixel groups PG_1, PG_2, PG_3, and PG_4 and the four display electrodes. In an embodiment of FIG. 1E, a size of each of the first to fourth pixel groups PG_1, PG_2, PG_3, and PG_4 is (8 μm×8 μm), and each of the pixel groups PG_1, PG_2, PG_3, and PG_4 includes 64 pixel electrodes each which has a size of (1 μm×1 μm). The 64 pixel electrodes included in each of the pixel groups PG_1, PG_2, PG_3, and PG_4 may be arranged in (8×8). Each of the four display electrodes included in the pixel cluster PC may be connected to an arbitrary pixel electrode included in each of the pixel groups PG_1, PG_2, PG_3, and PG_4, by an electrical wiring.

FIG. 1E illustrates that the pixel cluster PC is disposed on one pixel group (one of PG_1, PG_2, PG_3, and PG_4), but this is only one embodiment, and a position of the pixel cluster PC is not limited thereto. For example, the pixel cluster PC may be disposed in an area related to another adjacent pixel cluster. That is, a position of the pixel cluster PC may be random.

FIG. 2A is a view illustrating a result of calculating hologram data CGH.

FIG. 2A shows a calculation of computer-generated holography (hereinafter, CGH) data at (20K×20K) resolution. FIG. 2A shows pixel data output from pixel electrodes included in pixel groups corresponding to 80 pixel circuits arranged in (8×10). For example, an area ‘A’ shows pixel data output from pixel electrodes of a pixel group corresponding to one pixel circuit. A size of one pixel data is (1 μm×1 μm), and a size of one area ‘A’ shown in FIG. 2A is (8 μm×8 μm). Therefore, one area ‘A’ shown in FIG. 2A includes 64 pixels of data.

FIG. 2B is a view illustrating pixel data output from a pixel cluster of an apparatus for displaying a hologram according to an embodiment of the present disclosure.

In more detail, FIG. 2B is a view illustrating pixel data output from pixel clusters when the apparatus 100a (refer to FIG. 1A) for displaying the hologram illustrated in FIG. 1A is arranged in (4×5). Each area separated by a solid line in FIG. 2B indicates an area related to one pixel cluster. Each area separated by the solid line corresponds to each of the first to fourth pixel groups PG_1, PG_2, PG_3, and PG_4 (refer to FIG. 1A) illustrated in FIG. 1A. FIG. 2B illustrates that each pixel cluster is disposed within the solid line area associated with each pixel cluster, but is not limited thereto. For example, each pixel cluster may be disposed in a solid line area related to another adjacent pixel cluster. The display electrodes included in each pixel cluster may display pixel data for implementing a holographic image.

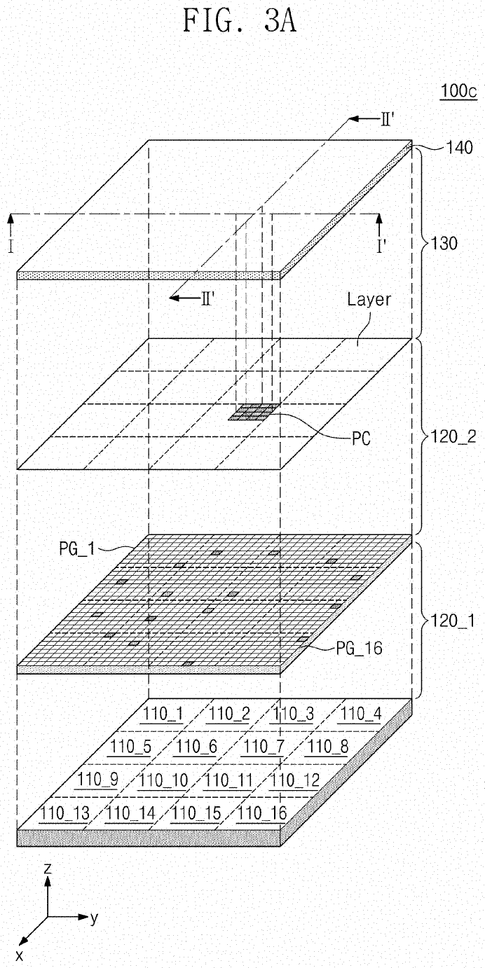

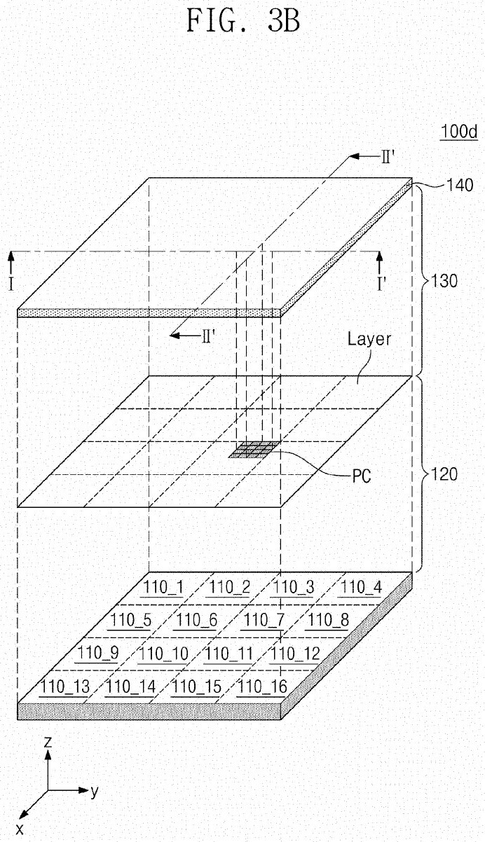

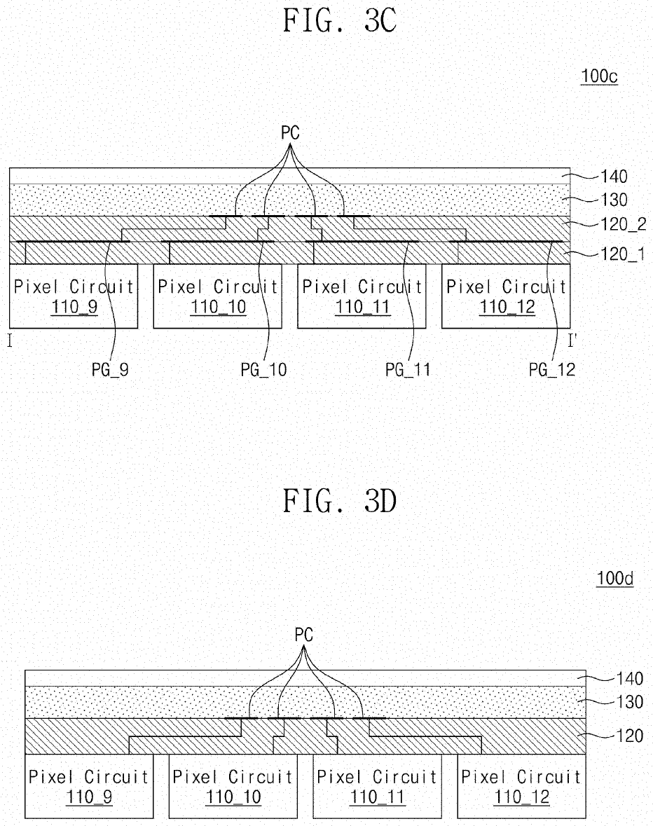

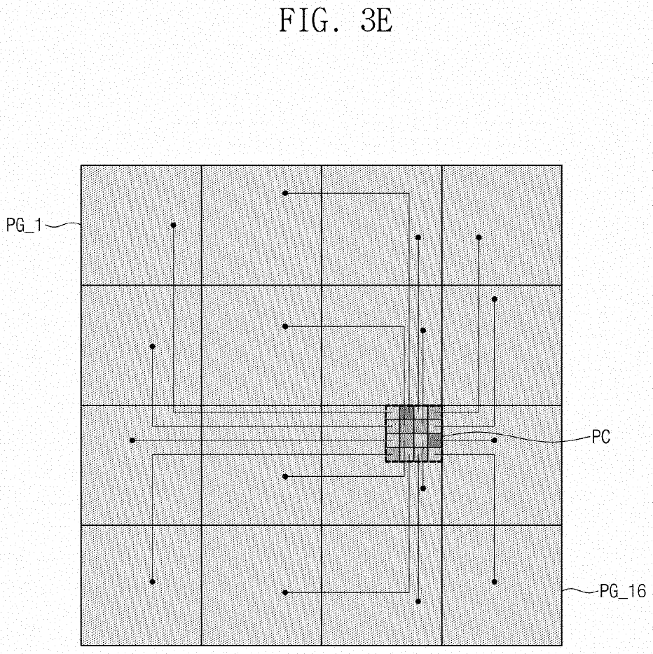

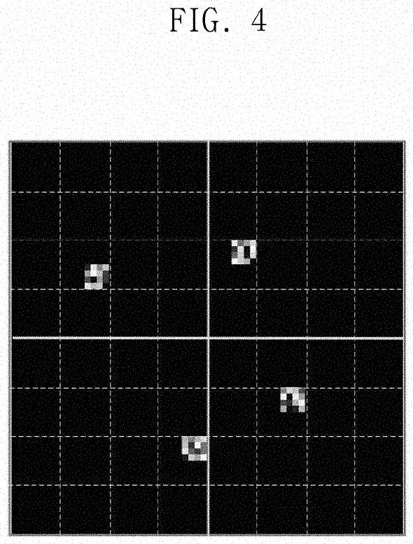

FIG. 3A is a view illustrating a structure of an apparatus for displaying a hologram according to an embodiment of the present disclosure.

In more detail, FIG. 3A shows an expanded embodiment of the apparatus 100a (refer to FIG. 1A) for displaying the hologram illustrated in FIG. 1A described above. Components of an apparatus 100c for displaying a hologram shown in FIG. 3A may have substantially the same functions and features as the components of the apparatus 100a for displaying the hologram shown in FIG. 1A. Hereinafter, in the apparatus for displaying the hologram 100c of FIG. 3A, a description reduplicated with that described above in FIG. 1A will be omitted.

Referring to FIG. 3A, the apparatus 100c for displaying the hologram according to an embodiment of the present disclosure may include first to sixteenth pixel circuits 110_1 to 110_16, the first insulating layer 120_1, first to sixteenth pixel groups PG_1 to PG_16, the second insulating layer 120_2, the pixel cluster PC, the display panel 130, and the common electrode 140. The first to sixteenth pixel circuits 110_1 to 110_16 may be disposed in the x direction and the y direction to form an array. FIG. 3A illustrates that the first to sixteenth pixel circuits 110_1 to 110_16 are arranged in (4×4).

The first insulating layer 120_1 may be stacked on the first to sixteenth pixel circuits 110_1 to 110_16. The first to sixteenth pixel groups PG_1 to PG_16 respectively corresponding to the first to sixteenth pixel circuits 110_1 to 110_16 may be formed on the first insulating layer 120_1. The first to sixteenth pixel groups PG_1 to PG_16 may be disposed in the x direction and the y direction to form an array. FIG. 3A illustrates the first to sixteenth pixel groups PG_1 to PG_16 are arranged in (4×4). In addition, it is shown that the plurality of pixel electrodes included in each of the first to sixteenth pixel groups PG_1 to PG_16 are arranged in (8×8) in the x direction and the y direction. The first to sixteenth pixel groups PG_1 to PG_16 may be electrically connected to the corresponding first to sixteenth pixel circuits 110_1 to 110_16 through lines, respectively.

The second insulating layer 120_2 may be stacked on the first to sixteenth pixel groups PG_1 to PG_16. The layer may be disposed on the second insulating layer 120_2. The layer refers to a top surface of the second insulating layer 120_2 and does not mean a physical component. The layer may include the pixel cluster PC. FIG. 3A illustrates the pixel cluster PC includes 16 display electrodes, and the 16 display electrodes are arranged in (4×4) in the x direction and the y direction. The pixel cluster PC will be randomly disposed on the layer. Each of the display electrodes included in the pixel cluster PC may be electrically connected to at least one pixel electrode included in each of the first to sixteenth pixel groups PG_1 to PG_16 through a line. Meanwhile, for simplicity, lines connecting the pixel electrodes of each pixel group and the pixels of the pixel cluster PC as shown in FIG. 1A are omitted.

The display panel 130 may be stacked on the layer. The common electrode 140 may be stacked on the display panel 130. A driving aspect of the apparatus 100c for displaying the hologram according to the embodiment of the present disclosure shown in FIG. 3A will be described in detail in FIG. 4 to be described later.

FIG. 3B is a view illustrating a structure of an apparatus for displaying a hologram according to another embodiment of the present disclosure.

In more detail, FIG. 3B illustrates an expanded embodiment of the apparatus 100b (refer to FIG. 1B) for displaying the hologram illustrated in FIG. 1B described above. Components of an apparatus 100d for displaying a hologram shown in FIG. 3B may have substantially the same functions and features as the components of the apparatus 100b for displaying the hologram shown in FIG. 1B. Hereinafter, in the apparatus 100d for displaying the hologram of FIG. 3B, detailed descriptions of functions, features, or operations reduplicated with those described above in FIG. 1B will be omitted.

Referring to FIG. 3B, the apparatus 100d for displaying the hologram according to an embodiment of the present disclosure may include the first to sixteenth pixel circuits 110_1 to 110_16, the insulating layer 120, the pixel cluster PC, the display panel 130, and the common electrode 140. The first to sixteenth pixel circuits 110_1 to 110_16 may be disposed in the x direction and the y direction to form an array. FIG. 3B illustrates the first to sixteenth pixel circuits 110_1 to 110_16 are arranged in (4×4).

The insulating layer 120 may be stacked on the first to sixteenth pixel circuits 110_1 to 110_16. The insulating layer 120 may include an organic insulator. The layer may be disposed on the insulating layer 120. The layer may include the pixel cluster PC. FIG. 3B illustrates the pixel cluster PC includes 16 display electrodes, and the 16 display electrodes are arranged in (4×4) in the x direction and the y direction. The pixel cluster PC will be randomly disposed on the layer. The display electrodes included in the pixel cluster PC may be electrically connected to the first to sixteenth pixel circuits 110_1 to 110_16 through lines, respectively. The display panel 130 may be stacked on the layer. The common electrode 140 may be stacked on the display panel 130.

FIG. 3C is a cross-sectional view taken along a line I-I′ of the apparatus for displaying the hologram illustrated in FIG. 3A.

FIG. 3C illustrates that four pixel circuits 110_9, 110_10, 110_11, and 110_12 of the 16 pixel circuits 110_1 to 110_16 (refer to FIG. 3A) shown in FIG. 3A. The first insulating layer 120_1 may be stacked on the ninth to twelfth pixel circuits 110_9, 110_10, 110_11, and 110_12. The ninth to twelfth pixel groups PG_9, PG_10, PG_11, and PG_12 may be formed on the first insulating layer 120_1. Each of the pixel groups PG_9, PG_10, PG_11, and PG_12 includes a plurality of pixel electrodes, but, for simplicity, the pixel electrodes constituting the pixel groups PG_9, PG_10, PG_11, and PG_12 are not shown in FIG. 3C. Each of the ninth to twelfth pixel groups PG_9, PG_10, PG_11, and PG_12 may correspond to and be electrically connected to the ninth to twelfth pixel circuits 110_9, 110_10, 110_11, and 110_12, respectively. The second insulating layer 120_2 may be stacked on the ninth to twelfth pixel groups PG_9, PG_10, PG_11, and PG_12. The pixel cluster PC may be formed on the second insulating layer 120_2.

FIG. 3C illustrates four display electrodes among the 16 display electrodes shown in FIG. 3A. The plurality of display electrodes included in the pixel cluster PC may be clustery arranged. Each of the plurality of display electrodes may be connected to an arbitrary pixel electrode included in each of the plurality of pixel groups PG_1 to PG_16 (refer to FIG. 3A). FIG. 3C conceptually illustrates that each of the four display electrodes is electrically connected to an arbitrary pixel electrode included in each of the ninth to twelfth pixel groups PG_9, PG_10, PG_11, and PG_12. The display panel 130 may be stacked on the second insulating layer 120_2, and the common electrode 140 may be stacked on the display panel 130. A cross-sectional view of the apparatus 100c for displaying the hologram shown in FIG. 3A taken along a line II-II′ is also the same as that of FIG. 3C.

FIG. 3D is a cross-sectional view taken along a line I-I′ of the apparatus for displaying the hologram illustrated in FIG. 3B.

FIG. 3D illustrates that four pixel circuits 110_9, 110_10, 110_11, and 110_12 among the 16 pixel circuits 110_1 to 110_16 (refer to FIG. 3B) shown in FIG. 3B. The insulating layer 120 may be stacked on the ninth to twelfth pixel circuits 110_9, 110_10, 110_11, and 110_12. The pixel cluster PC may be formed on the insulating layer 120.

FIG. 3D illustrates four display electrodes among the 16 display electrodes shown in FIG. 3B. The plurality of display electrodes included in the pixel cluster PC may be clustery arranged. The plurality of display electrodes may be electrically connected to the plurality of pixel circuits 110_1 to 110_16 (refer to FIG. 3B), respectively. FIG. 3D conceptually illustrates that the four display electrodes are electrically connected to the ninth to twelfth pixel circuits 110_9, 110_10, 110_11, and 110_12, respectively. The display panel 130 may be stacked on the insulating layer 120, and the common electrode 140 may be stacked on the display panel 130. A cross-sectional view of the apparatus 100d for displaying the hologram shown in FIG. 3B taken along a line IMP is also the same as that of FIG. 3D.

FIG. 3E is a plan view of the apparatus for displaying the hologram illustrated in FIG. 3A.

In more detail, FIG. 3E illustrates the first to sixteenth pixel groups PG_1 to PG_16 (refer to FIG. 3A), the pixel cluster PC including the 16 display electrodes, and a wiring structure between the pixel groups PG_1 to PG_16 and the 16 display electrodes. In an embodiment of FIG. 3E, each of the first to sixteenth pixel groups PG_1 to PG_16 has a size of (8 μm×8 μm), and each of the pixel groups PG_1 to PG_16 includes 64 pixel electrodes each which has a size of (1 μm×1 μm). The 64 pixel electrodes included in each of the pixel groups PG_1 to PG_16 may be arranged in (8×8). Each of the 16 display electrodes included in the pixel cluster PC may be connected to an arbitrary pixel electrode included in each of the pixel groups PG_1 to PG_16 by an electrical wiring.

FIG. 3E illustrates that the pixel cluster PC is disposed on one pixel group (any one of PG_1 to PG_16), but this is only an embodiment and does not limit a position of the pixel cluster PC thereto. For example, the pixel cluster PC may be disposed in an area related to another adjacent pixel cluster. That is, the position of the pixel cluster PC may be random.

FIG. 4 is a view illustrating pixel data output from a pixel cluster of an apparatus for displaying a hologram according to another embodiment of the present disclosure.

In more detail, FIG. 4 is a view illustrating pixel data output from pixel clusters when the apparatus 100c (refer to FIG. 3A) for displaying the hologram illustrated in FIG. 3A is arranged in (2×2). Each area separated by a solid line in FIG. 4 is an area related to one pixel cluster. Each area separated by the solid line corresponds to each of the first to sixteenth pixel groups PG_1 to PG_16 (refer to FIG. 3A) illustrated in FIG. 3A. FIG. 4 illustrates that each pixel cluster is located within the solid line area associated with each pixel cluster, but is not limited thereto. For example, each pixel cluster may be disposed in a solid line area related to another adjacent pixel cluster. The display electrodes included in each pixel cluster may display pixel data for implementing a holographic image.

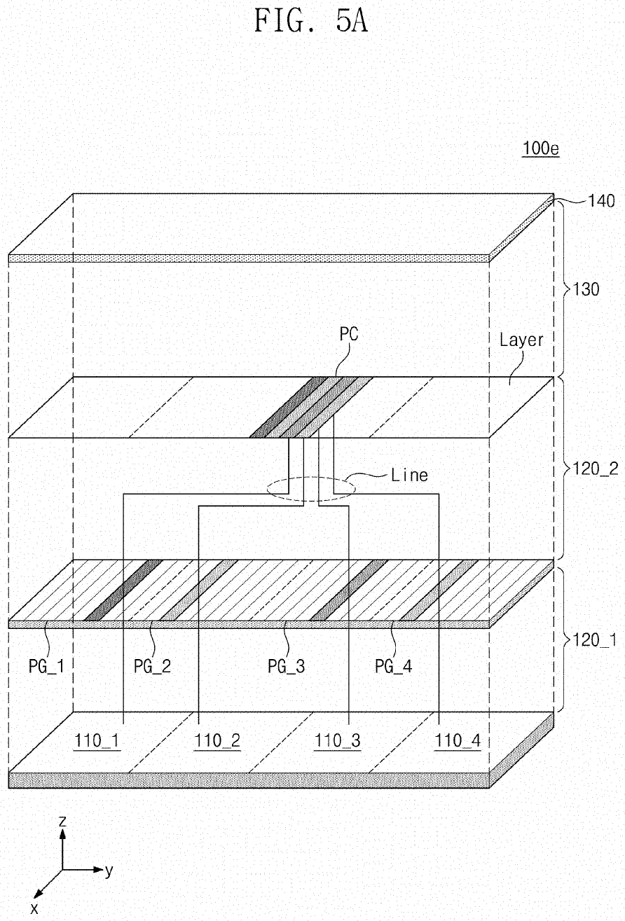

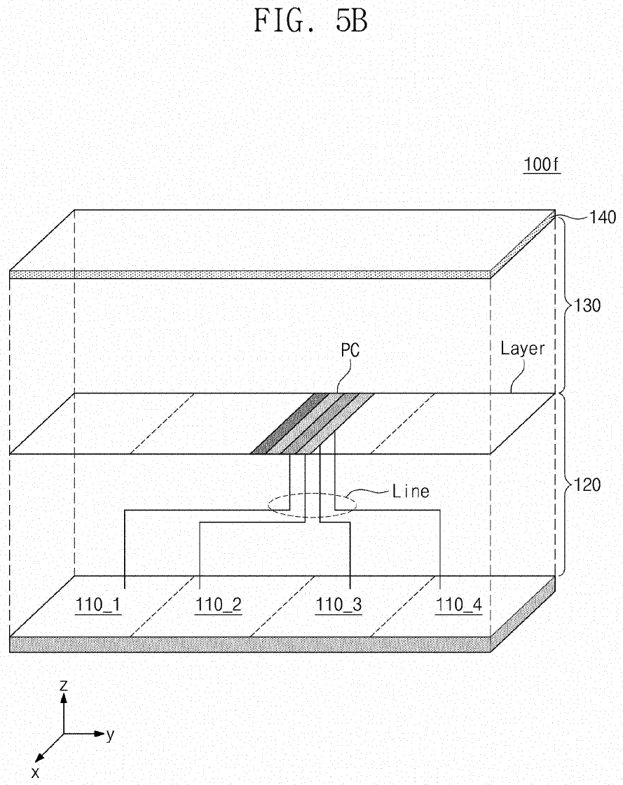

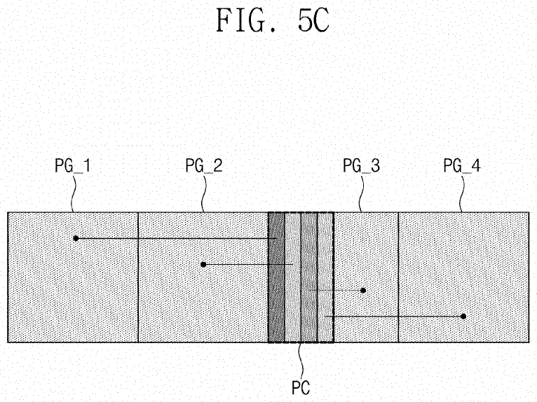

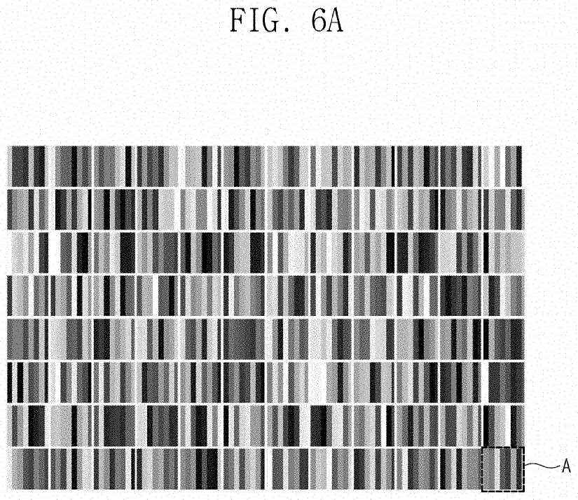

FIG. 5A is a view illustrating a structure of an apparatus for displaying a hologram according to an embodiment of the present disclosure.

In more detail, FIG. 5A illustrates an apparatus 100e for displaying a hologram including a pixel cluster PC including display electrodes disposed in a first direction (e.g., the y direction) and illustrates an expanded embodiment of the apparatus 100a for displaying the hologram (refer to FIG. 1A) including the square pixel cluster PC shown in FIG. 1A. Components of the apparatus 100e for displaying the hologram shown in FIG. 5A may have substantially the same functions and features as the components of the apparatus 100a for displaying the hologram shown in FIG. 1A. Hereinafter, in the apparatus 100e for displaying the hologram of FIG. 5A, a description reduplicated with that described above in FIG. 1A will be omitted.

Referring to FIG. 5A, the apparatus 100e for displaying the hologram according to an embodiment of the present disclosure may include the first to fourth pixel circuits 110_1, 110_2, 110_3, and 110_4, the first insulating layer 120_1, and the first to fourth pixel groups PG_1, PG_2, PG_3, and PG_4, the second insulating layer 120_2, the pixel cluster PC, the display panel 130, and the common electrode 140. The first to fourth pixel circuits 110_1, 110_2, 110_3, and 110_4 may be disposed in the x direction and the y direction to form an array. FIG. 5A illustrates the first to fourth pixel circuits 110_1, 110_2, 110_3, and 110_4 are arranged in (1×4).

The first insulating layer 120_1 may be stacked on the first to fourth pixel circuits 110_1, 110_2, 110_3, and 110_4. The first to fourth pixel groups PG_1, PG_2, PG_3, and PG_4 respectively corresponding to of the first to fourth pixel circuits 110_1, 110_2, 110_3, and 110_4 may be formed on the first insulating layer 120_1. The first to fourth pixel groups PG_1, PG_2, PG_3, and PG_4 may be disposed in the x direction and the y direction to form an array. FIG. 5A illustrates that the first to fourth pixel groups PG_1, PG_2, PG_3, and PG_4 are arranged in (1×4). In addition, it is shown that the plurality of pixel electrodes included in each of the first to fourth pixel groups PG_1, PG_2, PG_3, and PG_4 are arranged in (1×8). The first to fourth pixel groups PG_1, PG_2, PG_3, and PG_4 may be electrically connected to corresponding first to fourth pixel circuits 110_1, 110_2, 110_3, and 110_4 by lines, respectively.

The second insulating layer 120_2 may be stacked on the first to fourth pixel groups PG_1, PG_2, PG_3, and PG_4. The layer may be disposed on the second insulating layer 120_2. The layer refers to a top surface of the second insulating layer 120_2 and does not mean a physical component. The layer may include the pixel cluster PC. FIG. 5A illustrates the pixel cluster PC includes four display electrodes and the four display electrodes are arranged in (1×4) in the x direction and the y direction. The pixel cluster PC is randomly disposed on the layer. Each of the display electrodes included in the pixel cluster PC may be electrically connected to at least one pixel electrode included in each of the first to fourth pixel groups PG_1, PG_2, PG_3, and PG_4 through a line.

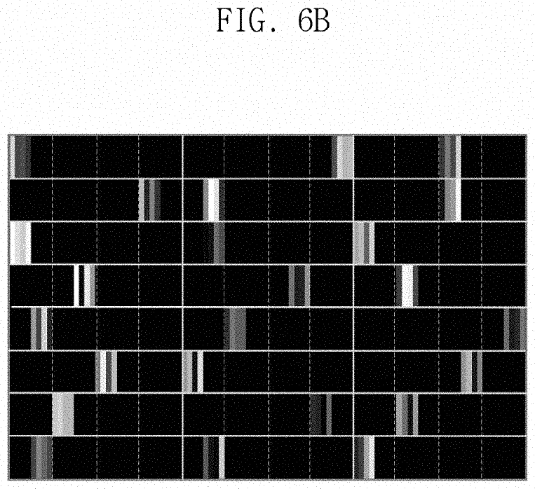

The display panel 130 may be stacked on the layer. The common electrode 140 may be stacked on the display panel 130. A driving aspect of the apparatus 100e for displaying the hologram according to the embodiment of the present disclosure shown in FIG. 5A will be described in detail with reference to FIGS. 6A and 6B to be described later.

FIG. 5B is a view illustrating a structure of an apparatus for displaying a hologram according to another embodiment of the present disclosure.

In more detail, FIG. 5B illustrates an apparatus 100f for displaying the hologram including a rectangular pixel cluster PC and illustrates an expanded embodiment of the apparatus 100b for displaying the hologram (refer to FIG. 1B) including the square pixel cluster PC illustrated in FIG. 1B. Components of the apparatus 100f for displaying the hologram shown in FIG. 5B may have substantially the same functions and features as the components of the apparatus 100b for displaying the hologram shown in FIG. 1B. Hereinafter, in the apparatus 100f for displaying the hologram of FIG. 5B, detailed descriptions of functions, features, or operations that reduplicate those described above in FIG. 1B will be omitted.

Referring to FIG. 5B, the apparatus 100f for displaying the hologram according to an embodiment of the present disclosure may include the first to fourth pixel circuits 110_1, 110_2, 110_3, and 110_4, the insulating layer 120, the pixel cluster PC, the display panel 130, and the common electrode 140. The first to fourth pixel circuits 110_1, 110_2, 110_3, and 110_4 may be disposed in the x direction and they direction to form an array. FIG. 5B illustrates the first to fourth pixel circuits 110_1, 110_2, 110_3, and 110_4 are arranged in (1×4).

The insulating layer 120 may be stacked on the first to fourth pixel circuits 110_1, 110_2, 110_3, and 110_4. The insulating layer 120 may include an organic insulator. The layer may be disposed on the insulating layer 120. The layer refers to a top surface of the insulating layer 120 and does not mean a physical component. The layer may include the pixel cluster PC. FIG. 5B illustrates that the pixel cluster PC includes the four display electrodes, and the four display electrodes are arranged in (1×4) in the x direction and the y direction. The pixel cluster PC is to be randomly disposed on the layer. The display electrodes included in the pixel cluster PC may be electrically connected to the first to fourth pixel circuits 110_1, 110_2, 110_3, and 110_4 through lines, respectively. The display panel 130 may be stacked on the layer. The common electrode 140 may be stacked on the display panel 130.

FIG. 5C is a plan view of the apparatus for displaying the hologram illustrated in FIG. 5A.

In more detail, FIG. 5C illustrates the first to fourth pixel groups PG_1, PG_2, PG_3, and PG_4 (refer to FIG. 5A), the pixel cluster PC including the four display electrodes, and a wiring structure between the first to fourth pixel groups PG_1, PG_2, PG_3, and PG_4 and the four display electrodes. In the embodiment of FIG. 5C, a size of each of the first to fourth pixel groups PG_1, PG_2, PG_3, and PG_4 is (8 μm×8 μm), and each of the pixel groups PG_1, PG_2, PG_3, and PG_4 includes 8 pixel electrodes each which has a size (1 μm×8 μm). The eight pixel electrodes included in each of the pixel groups PG_1, PG_2, PG_3, and PG_4 may be arranged in (1×8). Each of the four display electrodes included in the pixel cluster PC may be electrically connected to an arbitrary pixel electrode of each of the pixel groups PG_1, PG_2, PG_3, and PG_4 by an electrical wiring.

FIG. 5C illustrates that the pixel cluster PC is disposed on one pixel group (any one of PG_1, PG_2, PG_3, and PG_4), but this is only one embodiment, and a position of the pixel cluster PC is not limited thereto. For example, the pixel cluster PC may be disposed in an area related to another adjacent pixel cluster. That is, the position of the pixel cluster PC may be random.

FIG. 6A is a view illustrating a result of calculating other hologram data CGH.

FIG. 6A shows a calculation of CGH data of (2.5K×20K) resolution. FIG. 6A shows pixel data output from pixel electrodes included in pixel groups corresponding to 96 pixel circuits arranged in (8×12). For example, an ‘A’ area shows pixel data output from pixel electrodes of a pixel group corresponding to one pixel circuit. A size of one pixel data is (1 μm×8 μm), a size of one area ‘A’ shown in FIG. 6A is (8 μm×8 μm). Thus, one area ‘A’ shown in FIG. 6A includes 8 pixels of data.

FIG. 6B is a view illustrating pixel data output from a pixel cluster of an apparatus for displaying a hologram according to another embodiment of the present disclosure.

In more detail, FIG. 6B is a view illustrating pixel data output from pixel clusters when the apparatus 100e (refer to FIG. 5A) for displaying the hologram illustrated in FIG. 5A is arranged in (8×3). Each area separated by a solid line in FIG. 6B indicates an area related to one pixel cluster. Each area separated by the solid line corresponds to each of the first to fourth pixel groups PG_1, PG_2, PG_3, and PG_4 (refer to FIG. 5A). FIG. 6B illustrates that each pixel cluster is disposed within the solid line area associated with each pixel cluster, but is not limited thereto. For example, each pixel cluster may be disposed in a solid line area related to another adjacent pixel cluster. The display electrodes included in each pixel cluster may display pixel data for implementing a holographic image.

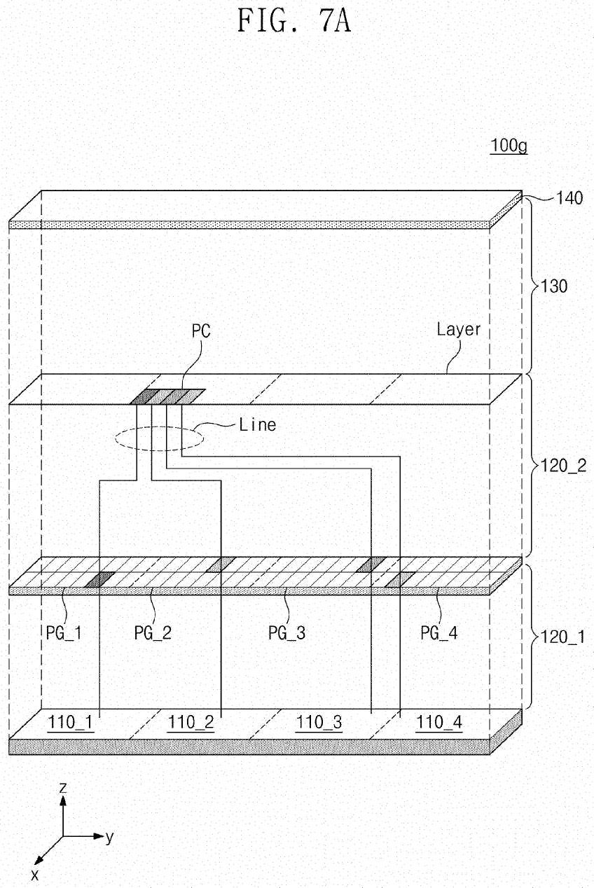

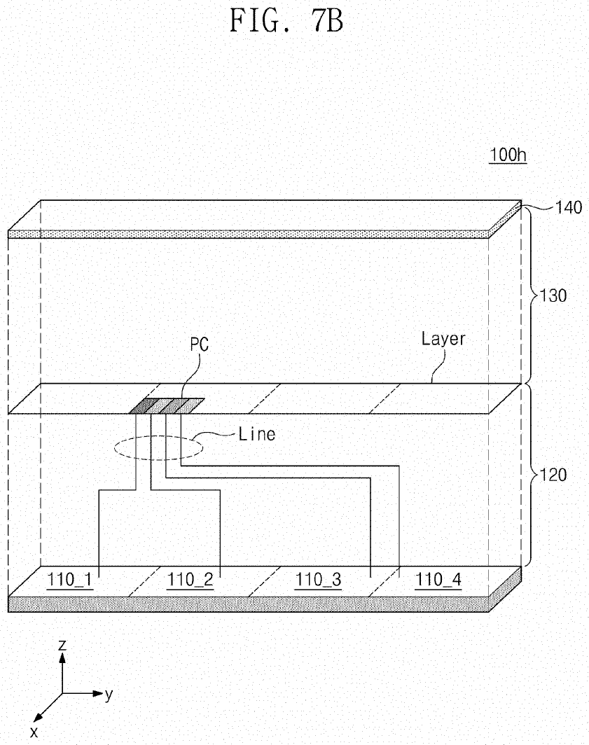

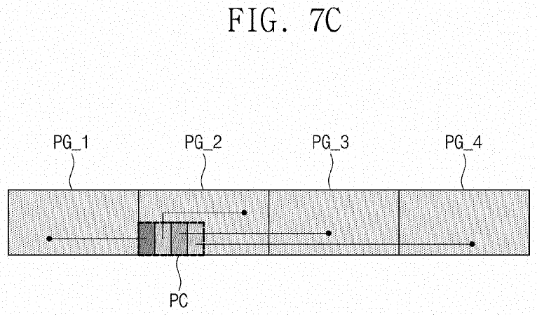

FIG. 7A is a view illustrating a structure of an apparatus for displaying a hologram according to an embodiment of the present disclosure.

In more detail, FIG. 7A shows an apparatus 100g for displaying a hologram including a rectangular pixel cluster PC and illustrates another embodiment different from the apparatus 100e for displaying the hologram (refer to FIG. 5A) including the rectangular pixel cluster PC illustrated in FIG. 5A. Components of the apparatus 100g for displaying the hologram shown in FIG. 7A may have substantially the same functions and characteristics as the components of the apparatus 100e for displaying the hologram shown in FIG. 5A. Hereinafter, in the apparatus 100g for displaying the hologram of FIG. 7A, detailed descriptions of functions, features, or operations that reduplicate those described above in FIG. 5A will be omitted.

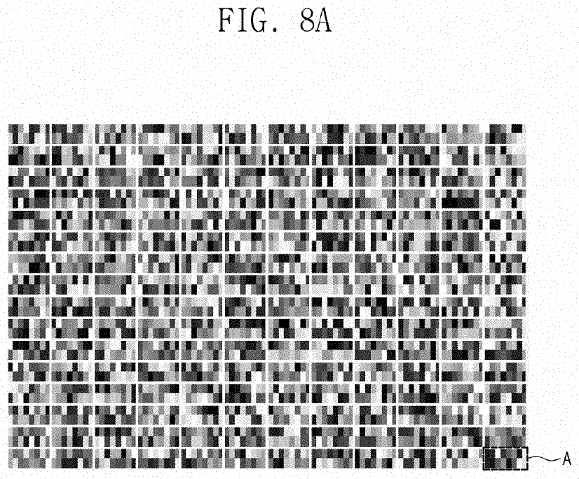

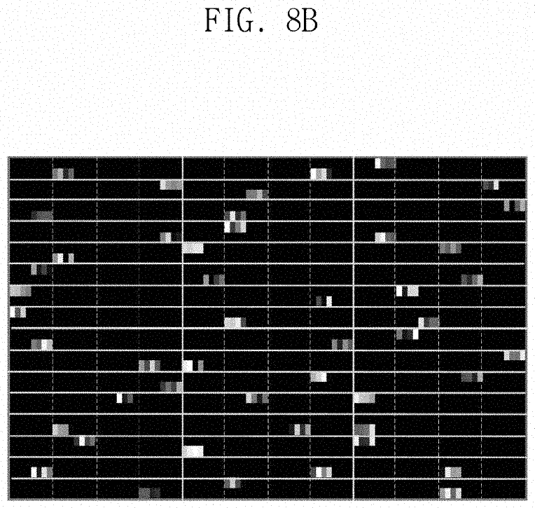

The apparatus 100g for displaying the hologram illustrated in FIG. 7A is different from the apparatus 100e for displaying the hologram illustrated in FIG. 5A in an arrangement of a plurality of pixel electrodes included in the first to fourth pixel groups PG_1, PG_2, PG_3, and PG_4. FIG. 7A illustrates that each of the first to fourth pixel groups PG_1, PG_2, PG_3, and PG_4 includes 16 pixel electrodes, and the 16 pixel electrodes are arranged in (2×8) in the x direction and the y direction. A driving aspect of the apparatus 100g for displaying the hologram according to the embodiment of the present disclosure shown in FIG. 7A will be described in detail in FIGS. 8A and 8B to be described later.

FIG. 7B is a view illustrating a structure of an apparatus for displaying a hologram according to another embodiment of the present disclosure.

In more detail, FIG. 7B illustrates an apparatus 100h for displaying the hologram including a rectangular pixel cluster PC and illustrates an expanded embodiment of the apparatus 100b for displaying the hologram (refer to FIG. 1B) including a square pixel cluster PC shown in FIG. 1B described above. Components of the apparatus 100h for displaying the hologram shown in FIG. 7B may have substantially the same functions and features as the components of the apparatus 100b for displaying the hologram shown in FIG. 1B. Hereinafter, in the apparatus 100h for displaying the hologram of FIG. 7B, detailed descriptions of functions, features, or operations reduplicating those described above in FIG. 1B will be omitted.

The apparatus 100h for displaying the hologram illustrated in FIG. 7B is different from the apparatus 100f for displaying the hologram illustrated in FIG. 5B in an arrangement of a plurality of pixel electrode included in the first to fourth pixel groups PG_1, PG_2, PG_3, and PG_4. FIG. 7B illustrates each of the first to fourth pixel groups PG_1, PG_2, PG_3, and PG_4 includes 16 pixel electrodes, and the 16 pixel electrodes are arranged in (2×8) in the x direction and the y direction.

FIG. 7C is a plan view of the apparatus for displaying the hologram illustrated in FIG. 7A.

In more detail, FIG. 7C illustrates the first to fourth pixel groups PG_1, PG_2, PG_3, and PG_4 (refer to FIG. 7A), the pixel cluster PC including the four display electrodes, and a wiring structure between the first to fourth pixel groups PG_1, PG_2, PG_3, and PG_4 and the four display electrodes. In the embodiment of FIG. 7C, a size of each of the first to fourth pixel groups PG_1, PG_2, PG_3, and PG_4 is (8 μm×4 μm), and each of the pixel groups PG_1, PG_2, PG_3, and PG_4 includes 16 sized pixel electrodes each which has a size of (1 μm×2 μm). The 16 pixel electrodes included in each of the pixel groups PG_1, PG_2, PG_3, and PG_4 may be arranged in (2×8). Each of the four display electrodes included in the pixel cluster PC may be connected to an arbitrary pixel electrode included in each of the pixel groups PG_1, PG_2, PG_3, and PG_4 by an electrical wiring.

FIG. 7C illustrates the pixel cluster PC is disposed on one pixel group (any one of PG_1, PG_2, PG_3, and PG_4), but this is only one embodiment, and a position of the pixel cluster PC is not limited thereto. For example, the pixel cluster PC may be disposed in an area related to another adjacent pixel cluster. That is, the position of the pixel cluster PC may be random.

FIG. 8A is a view illustrating a result of calculating other hologram data CGH.

FIG. 8A shows a calculation of CGH data of at (10K×20K) resolution. FIG. 8A shows pixel data output from pixel electrodes included in pixel groups corresponding to 192 pixel circuits arranged in (16×12). For example, an area ‘A’ shows pixel data output from pixel electrodes of a pixel group corresponding to one pixel circuit. A size of one pixel data is (1 μm×2 μm), and a size of one area ‘A’ shown in FIG. 8A is (8 μm×4 μm). Therefore, one area ‘A’ shown in FIG. 8A includes 16 pixels of data.

FIG. 8B is a view illustrating pixel data output from a pixel cluster of an apparatus for displaying a hologram according to another embodiment of the present disclosure.

In more detail, FIG. 8B is a view illustrating pixel data output from pixel clusters when the apparatus 100g (refer to FIG. 7A) for displaying the hologram illustrated in FIG. 7A is arranged in (16×3). Each area separated by a solid line in FIG. 8B indicates an area related to one pixel cluster. Each area separated by the solid line corresponds to each of the first to fourth pixel groups PG_1, PG_2, PG_3, and PG_4 (refer to FIG. 7A) illustrated in FIG. 7A. FIG. 8B illustrates each pixel cluster is disposed within the solid line area associated with each pixel cluster, but is not limited thereto. For example, each pixel cluster may be disposed in a solid line area related to another adjacent pixel cluster. The display electrodes included in each pixel cluster may display pixel data for implementing a holographic image.

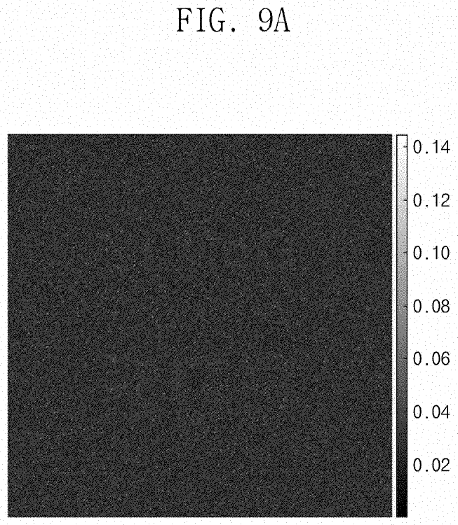

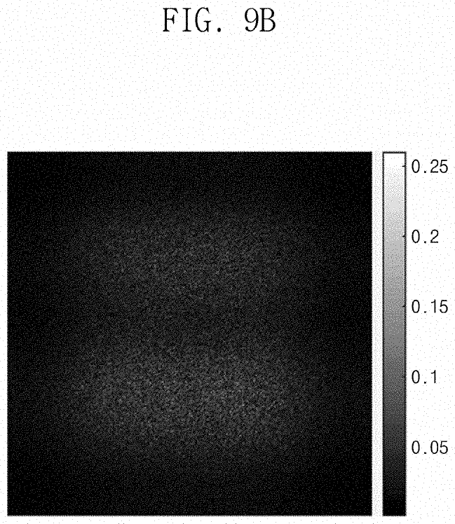

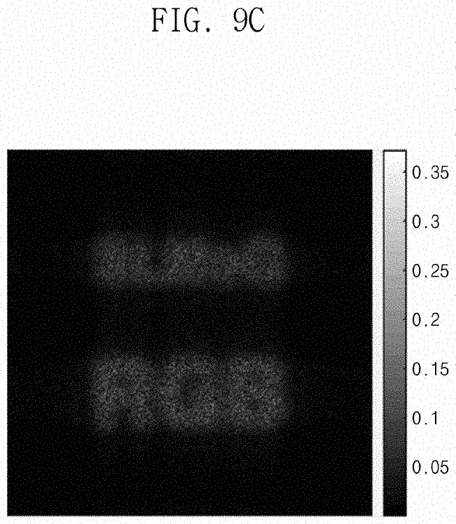

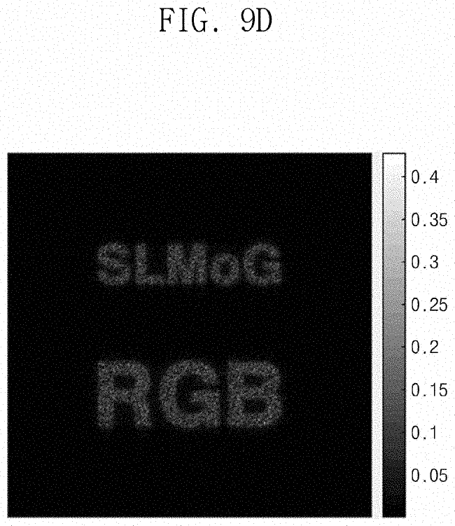

FIGS. 9A to 9D are views illustrating simulation results of a hologram image implemented from an apparatus for displaying a hologram according to an embodiment of the present disclosure.

In more detail, FIG. 9A is a view illustrating a simulation result when one display electrode having a size of (1 μm×1 μm) forms a pixel cluster on one pixel group having a size of (8 μm×8 μm). FIG. 9B is a view illustrating a simulation result when 16 pixel groups each which has a size of (8 μm×8 μm) are arranged in (4×4), and 16 display electrodes each which has a size of (1 μm×1 μm) form a pixel cluster. FIG. 9C is a view illustrating a simulation result when 400 pixel groups each which has a size of (8 μm×8 μm) are arranged in (20×20), and 400 display electrodes each which has a size of (1 μm×1 μm) form a pixel cluster. FIG. 9D is a view illustrating a simulation result when 10000 pixel groups each which has a size of (8 μm×8 μm) are arranged in (100×100), and 10000 display electrodes each which has a size of (1 μm×1 μm) form a pixel cluster.

Comparing FIGS. 9A to 9D, it may be seen that as the size of the pixel cluster increases, a holographic image to be desired is clearly implemented. In addition, it may be seen that as the size of the pixel cluster increases, a degree of noise removal is higher. That is, in the apparatus for displaying the hologram according to the present disclosure, the pixel cluster including the plurality of display electrodes may be formed, thereby securing a panel size favorable for viewing the holographic image, increasing a viewing angle of the holographic image, and reducing noise in the implemented image.

In the present specification, the arrangement of the plurality of display electrodes included in the pixel cluster presented as an embodiment is shown in the square or rectangular shape, but is not limited to a tetragonal arrangement, and it is sufficient when the plurality of display electrodes are clustery arranged. In addition, it is shown that the pixel cluster presented as an embodiment in the present specification is disposed within the area related to the pixel cluster, but it is safe to be disposed in the area related to another adjacent pixel cluster. Meanwhile, the size of each pixel cluster may be smaller than or equal to the area of an area associated with each pixel cluster.

In this specification, it is described that the pixel clusters are randomly arranged to display the holographic image, but the arrangement of the pixel clusters is not limited to the random one. That is, even when the pixel clusters are periodically arranged, the effect of the present disclosure may be derived. When the pixel clusters are arranged periodically, it is possible to alleviate the noise of the holographic image implemented in the same manner as when the pixel clusters are arranged randomly. However, when the pixel clusters are arranged periodically, a difference in brightness of the image may occur due to interference of light depending on an observation position. Therefore, to implement the clear holographic image, it may be desirable to randomly arrange pixel clusters, but when the difference in brightness of the image recognized by an observer is not large, periodically arranging the groups may be more practical in terms of a manufacturing process.

According to the apparatus for displaying the hologram according to the present disclosure, it is possible to produce the holographic image with the extended viewing angle.

According to the apparatus for displaying the hologram according to the present disclosure, the conventional panel having the large pixel is used, but the noise occurring in the holographic image may be solved.

The above-described contents are specific examples for carrying out the present disclosure. The present disclosure will include not only the above-described embodiments, but also embodiments capable of being simply changed or easily changed. In addition, the present disclosure will also include techniques capable of being easily modified and implemented using the embodiments. Therefore, the disclosed subject matter should not be limited to any single embodiment described herein, and the scope of the present disclosure shall be determined according to the attached claims.

What is claimed is:

1. An apparatus for displaying a hologram comprising:
a pixel circuit array including first to n^{th} pixel circuits;
a first insulating layer provided on the pixel circuit array;
first to n^{th} pixel electrodes provided on the first insulating layer and configured to be electrically connected to the first to n^{th} pixel circuits, respectively;
a second insulating layer provided on the first insulating layer;
first to n^{th} display electrodes provided on the second insulating layer and configured to be electrically connected to the first to n^{th} pixel electrodes, respectively;
a display panel formed on the first to n^{th} display electrodes; and
a common electrode formed on the display panel,
wherein the first to n^{th} display electrodes are clustery formed, and
wherein an area of the first to n^{th} display electrodes is smaller than an area of the pixel circuit array.

2. The apparatus for displaying the hologram of claim 1, wherein the first to n^{th} display electrodes are clustery formed in a square.

3. The apparatus for displaying the hologram of claim 1, wherein the first to n^{th} display electrodes are clustery formed in a rectangular shape.

4. The apparatus for displaying the hologram of claim 1, wherein at least two of the first to n^{th} display electrodes are clustery formed adjacent to each other.

5. The apparatus for displaying the hologram of claim 1, wherein the first insulating layer and the second insulating layer include the same material.

6. The apparatus for displaying the hologram of claim 5, wherein the first insulating layer and the second insulating layer include an organic insulator.

7. The apparatus for displaying the hologram of claim 1, wherein the display panel includes a liquid crystal (LC), an electrochromic (EC), an organic light-emitting diode (OLED), or a quantum dot.

8. An apparatus for displaying a hologram comprising:
a pixel circuit array including first to n^{th} pixel circuits;
an insulating layer provided on the pixel circuit array;
first to n^{th} display electrodes provided on the insulating layer and configured to be electrically connected to the first to n^{th} pixel circuits, respectively;
a display panel formed on the first to n^{th} display electrodes; and
a common electrode formed on the display panel,
wherein the first to n^{th} display electrodes are clustery formed, and
wherein an area of the first to n^{th} display electrodes is smaller than an area of the pixel circuit array.

9. The apparatus for displaying the hologram of claim 8, wherein the first to n^{th} display electrodes are clustery formed in a square.

10. The apparatus for displaying the hologram of claim 8, wherein the first to n^{th} display electrodes are clustery formed in a rectangular shape.

11. The apparatus for displaying the hologram of claim 8, wherein at least two of the first to n^{th} display electrodes are clustery formed adjacent to each other.

12. The apparatus for displaying the hologram of claim 8, wherein the insulating layer is an organic insulator.

13. The apparatus for displaying the hologram of claim 8, wherein the display panel includes a liquid crystal (LC), an electrochromic (EC), an organic light-emitting diode (OLED), or a quantum dot.
